(19) United States
(12) Patent Application Publication
(10) Pub. No.: US 2006/0103265 A1
(43) Pub. Date: May 18, 2006

(54) Ultrasonic transducer array and method of manufacturing the same

(75) Inventor: Tetsu Miyoshi, Kaisei-machi (JP)

Correspondence Address: SUGHRUE MION, PLLC, 2100 PENNSYLVANIA AVENUE, N.W., SUITE 800, WASHINGTON, DC, 20037, US

(73) Assignee: FUJI PHOTO FILM CO., LTD.

(21) Appl. No.: 11/270,528

(22) Filed: Nov. 10, 2005

(30) Foreign Application Priority Data
Nov. 12, 2004 (JP) 2004-328488
Mar. 24, 2005 (JP) 2005-086752

(51) Int. Cl. H02N 2/00; H01L 41/04

(52) U.S. Cl. 310/326

(57) ABSTRACT

A method of manufacturing an ultrasonic transducer array in which plural ultrasonic transducers are arranged on a curved surface with narrow pitches and narrow gaps. The method includes the steps of: (a) preparing a substrate having a curved surface; (b) forming a lower electrode layer on the curved surface of the substrate; (c) forming a piezoelectric material layer on the lower electrode layer; (d) forming an upper electrode layer on the piezoelectric material layer; and (e) forming grooves having predetermined widths with predetermined pitches in a multilayered structure including the lower electrode layer, the piezoelectric material layer and the upper electrode layer formed at steps (b) to (d) so as to form the plural ultrasonic transducers.

### BACKGROUND OF THE INVENTION

1. Field of the Invention

The present invention relates to an ultrasonic transducer array to be used for transmitting and receiving ultrasonic waves in an ultrasonic probe provided in an ultrasonic imaging apparatus, ultrasonic endoscope or the like. Further, the present invention relates to a method of manufacturing the ultrasonic transducer array.

2. Description of a Related Art

In an ultrasonic probe provided in an ultrasonic imaging apparatus for medical application or the like, various improvements have been made in order to improve the image quality of ultrasonic images or reduce physical loads on an object to be inspected. For example, characteristics of ultrasonic transducers (hereinafter, also referred to “elements”) for transmitting and receiving ultrasonic waves have been improved in order to improve intensity of transmission ultrasonic waves and/or reception sensitivity, and elements have been highly integrated in order to improve resolution of ultrasonic images. Further, in a probe of an ultrasonic endoscope to be used by being inserted into the object, it has been desired that the entire probe is downsized while its performance is maintained.

By the way, among various proves which can be used in ultrasonic imaging, there are probes including an ultrasonic transducer array in which plural elements are arranged on a curved surface like convex type probes or radial scan type probes. Such an ultrasonic transducer array is fabricated in the following manner, for example. First, as shown in FIG. 20A, electrode layers 901 and 902 are provided on both sides of a plate-like piezoelectric material layer 900 formed of a piezoelectric ceramic or the like, and further, acoustic materials (an acoustic matching layer 903, a backing material, etc.) are provided thereon. These layers 900 to 903 are placed on a planer substrate (sheet) 904 having flexibility, and then, grooves 905 are formed by using a precision cutting grinding wheel. Thereby, those layers 900 to 903 are divided into plural elements 910 while remaining on the substrate 904. Then, as shown in FIG. 20B, the substrate 904 is curved to have a desired curvature. Thereby, an ultrasonic transducer array including plural elements 910 arranged along the curved surface of the substrate 904 is fabricated.

As a related technology, Japanese Patent Application Publication JP-A-58-54939 discloses an ultrasonic probe having plural piezoelectric vibrators each having electrodes attached on both sides thereof and one or more acoustic matching layer in close contact with one electrode surface of each piezoelectric vibrator. The acoustic matching layer is formed of a flexible material and a group of piezoelectric vibrators are arranged such that their acoustic wave emission surfaces form a curved line or curved surface in order to arrange a row of ultrasonic vibrators to form a curved line easily, inexpensively and uniformly.

Further, Japanese Patent Application Publication JP-A-60-124199 discloses an ultrasonic probe in which arrayed vibrators and a thin backing material are bonded and curved to have a predetermined radius of curvature, a thick backing material is molded and fixed to the thin backing material, and both backing materials have the same acoustic impedance in order to obtain a desired curvature and prevent a cutting gap from increasing, and further, prevent reflection of ultrasonic waves from a rear surface of the backing material.

On the other hand, recent years, study on fabrication of ultrasonic transducers by film formation has been made, and the aerosol deposition method attracts attention as one film formation technology. The aerosol deposition method (hereinafter, also referred to as “AD method”) is a deposition method of generating an aerosol containing a material powder and spraying it on a substrate, and depositing the powder thereon by the collision energy, and also referred to as “injection deposition method” or “gas deposition method”. Here, an aerosol refers to fine particles of a solid or liquid floating in a gas. Since multiple dense and strong films can be stacked without using an adhesive or the like according to the AD method, future application is expected.

As a related technology, Japanese Patent Application Publication JP-A-6-285063 discloses an ultrasonic transducer having an piezoelectric element layer, acoustic matching layer and damping layer as basic component elements and at least one layer of the basic component elements is formed by injection deposition of ultrafine particles in order to improve performance and realize drastic cost reduction by manufacturing it without using any adhesive layer or requiring any cutting step.

However, as shown in FIGS. 20A and 20B, in the case where the ultrasonic transducer array is fabricated by curving the substrate 904, it is difficult to precisely arrange the plural elements 910. Further, since mechanical loads are placed on the respective elements 910 when the substrate 904 is curved, the piezoelectric material layer as a thin brittle material is easy to break. Accordingly, assembly precision and manufacture yield of the ultrasonic transducer array become lower, which cause cost rise and reduction in reliability of ultrasonic images. Further, as shown in FIG. 20A, the minimum value of processing width W_{GAP} of grooves formed by using the precision cutting grinding wheel has a limitation. On the other hand, as shown in FIGS. 20B and 20C, in the case where the widths W_{GAP} are the same, when the radius of curvature of the substrate 904 is made smaller (R₂<R₁), the angle formed by adjacent two elements 910 becomes larger (θ₂>θ₁). Therefore, as the ultrasonic transducer array is made smaller, the spacing between the adjacent elements 910 becomes larger, and the resolution of ultrasonic images becomes decreasingly lower.

Further, as shown in FIG. 21, it is conceivable that plural elements 920 are formed directly on the curved surface of a substrate 921 by the AD method using a mask as disclosed in JP-A-6-285063. However, in the AD method, since ceramic fine particles collide against the substrate or the like at a speed of several hundreds of meters per second, it is necessary to improve the strength of the mask for bearing such an impact. For this purpose, in a mask 922, the width W of a region other than an aperture 923 must be made larger or the depth D of the mask 922 must be made larger. As a result, it becomes difficult to arrange the elements 920 on a curved surface with narrow pitches and narrow gaps, and the angle θ₃ formed by adjacent two elements 920 becomes larger than the angle θ₂ shown in FIG. 20C. Further, the side surfaces of the elements 920 are easily tapered. Therefore, according to such a method, it is more difficult to realize microfabrication and high integration of elements than according to the method using dicing as shown in FIGS. 20A to 20C.

### SUMMARY OF THE INVENTION

The present invention has been achieved in view of the above-mentioned problems. An object of the present invention is to provide an ultrasonic transducer array, in which plural ultrasonic transducers are arranged on a curved surface with narrow pitches and narrow gaps, with high yield.

In order to attain the above-mentioned object, a method, according to a first aspect of the present invention is a method of manufacturing an ultrasonic transducer array including plural ultrasonic transducers arranged on a curved surface, and includes the steps of: (a) preparing a substrate having a curved surface; (b) forming a first conducting material layer on the curved surface of the substrate; (c) forming a piezoelectric material layer on the first conducting material layer; (d) forming a second conducting material layer on the piezoelectric material layer; and (e) forming plural grooves having predetermined widths with predetermined pitches in a multilayered structure including the first conducting material layer, the piezoelectric material layer and the second conducting material layer formed at steps (b) to (d) so as to form the plural ultrasonic transducers.

Further, a method according to a second aspect of the present invention is a method of manufacturing an ultrasonic transducer array including plural ultrasonic transducers arranged on a curved surface, and includes the steps of: (a) preparing a substrate having a curved surface; (b) forming a first conducting material layer on the curved surface of the substrate; (c) alternately stacking plural piezoelectric material layers and at least one internal electrode layer on the first conducting material layer; (d) forming a second conducting material layer on an uppermost one of the plural piezoelectric material layers; and (e) forming plural grooves having predetermined widths with predetermined pitches in a multilayered structure including the first conducting material layer, the plural piezoelectric material layers, the at least one internal electrode layer and the second conducting material layer formed at steps (b) to (d) so as to form the plural ultrasonic transducers.

Furthermore, an ultrasonic transducer array according to the present invention includes: a backing material having a curved surface; and plural ultrasonic transducers arranged on the curved surface of the backing material directly or indirectly, each of the plural ultrasonic transducers including a first conducting material layer, a piezoelectric material layer and a second conducting material layer, and a surface of the piezoelectric material layer at an opposite side to the backing material having an area larger than that of another surface of the piezoelectric material layer at a side of the backing material.

According to the present invention, since plural elements are formed by forming grooves in a multilayered structure formed on a curved element arrangement surface of a substrate, an ultrasonic transducer array, in which plural ultrasonic transducers are arranged on a curved surface with narrow pitches and narrow gaps, can be easily fabricated. Therefore, an ultrasonic transducer capable of transmitting and receiving ultrasonic waves with high resolution can be manufactured with high yield and at low cost.

### BRIEF DESCRIPTION OF THE DRAWINGS

FIGS. 1A to 1C show a configuration of an ultrasonic transducer array according to the first embodiment of the present invention;

FIG. 2 is a schematic view showing an ultrasonic probe including the ultrasonic transducer array according to the first embodiment of the present invention;

FIGS. 3A and 3B show a state in which ultrasonic waves are transmitted from the ultrasonic transducer array according to the first embodiment of the present invention in comparison with that in a conventional ultrasonic transducer array;

FIGS. 4A to 4E are diagrams for explanation of a method of manufacturing the ultrasonic transducer array according to the first embodiment of the present invention;

FIG. 5 is a schematic diagram showing a configuration of a film forming device used when the ultrasonic transducer array according to the first to seventh embodiments of the present invention is manufactured;

FIGS. 6A and 6B are enlarged views of a nozzle part of the film forming device shown in FIG. 5;

FIGS. 7A to 7C are diagrams for explanation of a method of manufacturing the ultrasonic transducer array according to the first embodiment of the present invention;

FIG. 8 is a plan view showing a configuration of an ultrasonic transducer array according to the second embodiment of the present invention;

FIGS. 9A to 9D are diagrams for explanation of a method of manufacturing the ultrasonic transducer array according to the second embodiment of the present invention;

FIGS. 10A to 10C are diagrams for explanation of the method of manufacturing the ultrasonic transducer array according to the second embodiment of the present invention;

FIGS. 11A to 11D are diagrams for explanation of a method of manufacturing an ultrasonic transducer array according to the third embodiment of the present invention;

FIGS. 12A and 12B are diagrams for explanation of a method of manufacturing an ultrasonic transducer array according to the fourth embodiment of the present invention;

FIGS. 13A to 13H are diagrams for explanation of the method of manufacturing the ultrasonic transducer array according to the fourth embodiment of the present invention;

FIGS. 14A to 14C are diagrams for explanation of the method of manufacturing the ultrasonic transducer array according to the fourth embodiment of the present invention;

FIG. 15 is a sectional view showing a modified example of the ultrasonic transducer array according to the fourth embodiment of the present invention;

FIG. 16 is a perspective view showing an ultrasonic transducer array according to the fifth embodiment of the present invention;

FIG. 17 is a perspective view showing an ultrasonic transducer array according to the sixth embodiment of the present invention;

FIGS. 18A and 18B are plan views showing a configuration of an ultrasonic transducer array according to the seventh embodiment of the present invention;

FIGS. 19A and 19B are diagrams for explanation of a modified example of the ultrasonic transducer array according to the first to seventh embodiments of the present invention;

FIGS. 20A to 20C are diagrams for explanation of a conventional method of fabricating an ultrasonic transducer array in which plural elements are arranged on a curved surface; and

FIG. 21 shows a state in which the ultrasonic transducer array in which plural elements are arranged on a curved surface is fabricated by an AD method using a mask.

### DESCRIPTION OF THE PREFERRED EMBODIMENTS

Hereinafter, preferred embodiments of the present invention will be described in detail by referring to the drawings. The same reference numerals are assigned to the same component elements and the description thereof will be omitted.

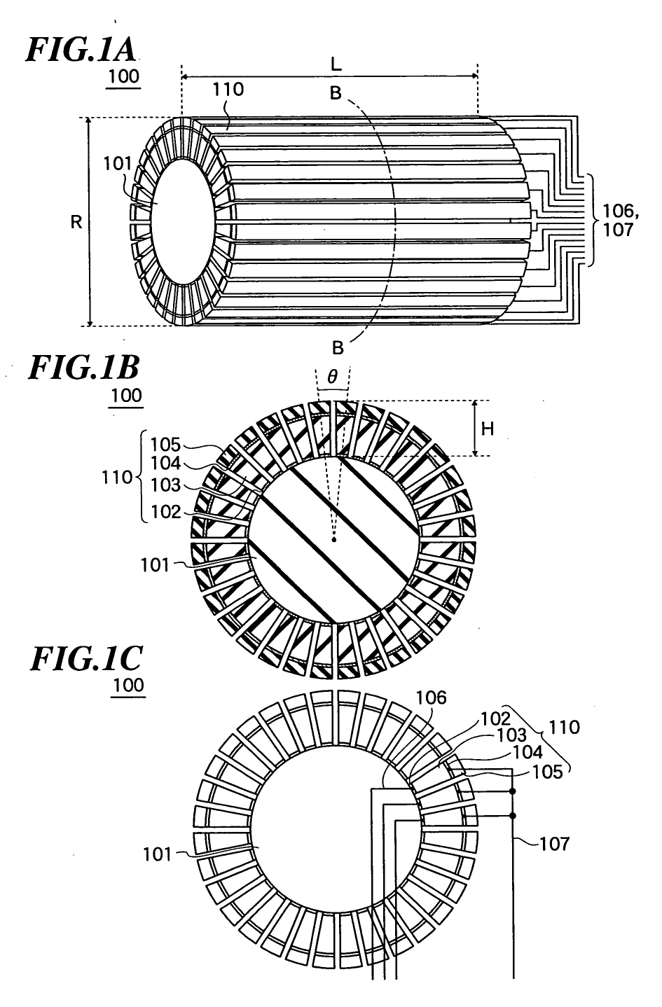

FIGS. 1A to 1C show a configuration of an ultrasonic transducer array according to the first embodiment of the present invention. As shown in FIG. 1A, an ultrasonic transducer array 100 according to the embodiment includes a backing material 101 formed of a cylinder and plural ultrasonic transducers (hereinafter, also referred to “elements”) 110 arranged on the cylindrical side surface of the backing material 101. The ultrasonic transducer array 100 as a whole has a cylindrical shape having diameter R of about 10 mm and length L of about 20 mm, for example. Within the array, the diameter of the backing material 101 is about 5 mm, for example, and height H of each element 110 is about 2.5 mm or less, for example. Such an ultrasonic transducer array 100 is used in the radial scan method for scanning the interior of an object to be inspected while rotating the transmission direction of ultrasonic waves. Although simplified and shown in FIGS. 1A to 1C, actually, the larger number of elements (e.g., 192 elements, i.e., 192 channels) are arranged around the backing material 101.

FIG. 1B shows a section of the ultrasonic transducer array 100 along B-B shown in FIG. 1A. Further, FIG. 1C shows one end surface (at a right side in FIG. 1A) of the ultrasonic transducer array 100 shown in FIG. 1A.

As shown in FIG. 1B, each element 110 includes a piezoelectric material 103 and a lower electrode 102 and an upper electrode 104 provided on both ends of the piezoelectric material 103.

The piezoelectric material 103 is formed of a material having a piezoelectric property such as a piezoelectric ceramic represented by PZT (Pb (lead) zirconate titanate) or a polymeric piezoelectric element represented by PVDF (polyvinylidene difluoride). The height of the piezoelectric material 103 is generally about 100 μm to 500 μm, and generally about 200 μm or less in the case of an element for high frequency waves.

Further, as shown in FIG. 1C, on one end surf ace of the ultrasonic transducer array 100, wiring 106 is drawn from the lower electrode 102 and wiring 107 is drawn from the upper electrode 104. Specifically, these drawn wirings 106 and 107 are formed by providing a wiring board on the one surface of the ultrasonic transducer array 100. When a voltage is applied to the lower electrode 102 and the upper electrode 104 provided on both ends of the piezoelectric material 103 by transmitting pulse or continuous wave electric signals via these wirings 106 and 107, the piezoelectric material 103 expands and contracts. By the expansion and contract, pulse or continuous wave ultrasonic waves are generated from each element 110. Further, each element expands and contracts by receiving propagating ultrasonic waves and generates an electric signal. The electric signal is output as a detection signal of ultrasonic waves. One of the lower electrode 102 and the upper electrode 104, desirably, the upper electrode 104 may be used as a common electrode. In this case, as shown in FIG. 1C, the wiring 107 may be commonly connected at a location distant from the upper electrode 104, or an electrode for electrically connecting the plural upper electrodes 104 exposed on the end surface of the ultrasonic transducer array to one another may be further formed.

The backing material 101 is formed of a material that easily absorb ultrasonic waves like a polyimide resin or a material containing a polyimide resin, for example. The backing material 101 suppresses the noise due to multiple reflection of ultrasonic waves within the ultrasonic transducer array 100 by absorbing the ultrasonic waves generated from the elements 110 and attenuate them quickly.

Further, the element 110 may include an acoustic matching layer 105 provided on the upper surface of the upper electrode 104. The acoustic matching layer 105 is formed of silica (SiO₂), glass or the like, and provided for efficiently propagating the ultrasonic waves generated from the piezoelectric material 103 to the object.

As will be described later, the plural elements 110 arranged on the cylindrical side surface of the backing material 101 are formed by forming grooves along a direction of the length L and dividing the piezoelectric material etc. having a circular cylindrical shape. Accordingly, as shown in FIG. 1B, widths of grooves that separate adjacent elements 110 are nearly constant. Thereby, the section of each element 110 forms a part of a sector radially spreading from the inner side (the lower electrode 102 side) to the outer side (the upper electrode 104 side). Therefore, in each element 110, the area at the upper surface is larger than the area at the lower surface. Further, the ultrasonic wave transmission surface of each element 110 is curved such that the section thereof forms a circular arc.

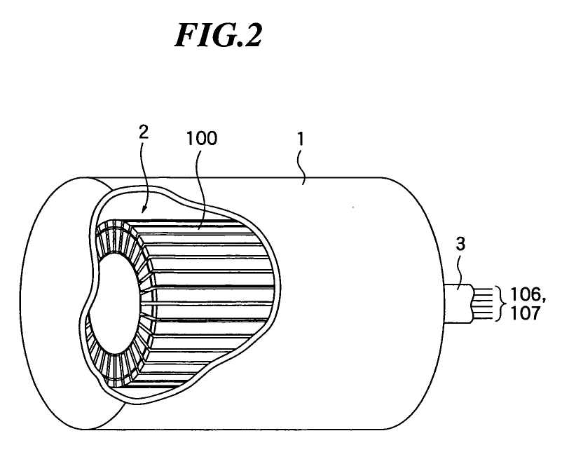

FIG. 2 is a schematic view showing an overview of an ultrasonic probe including the ultrasonic transducer array 100 shown in FIGS. 1A to 1C. The ultrasonic transducer array 100 is accommodated in a casing 1 and connected to an ultrasonic imaging apparatus main body via the wirings 106 and 107 protected by a covering material 3. Further, a liquid 2 such as water is provided between the ultrasonic transducer array 100 and the casing 1 in order to match the acoustic impedance with the object. Such an ultrasonic probe is, for example, mounted in the leading end of a scope of an endoscopic apparatus and inserted into the object, and the interior of the object is scanned with ultrasonic waves according to the radial scan method. That is, the ultrasonic transducer array 100 sequentially transmits ultrasonic waves while rotating one or plural ultrasonic wave transmission directions over 360-degree around and receives ultrasonic echoes generated within the object.

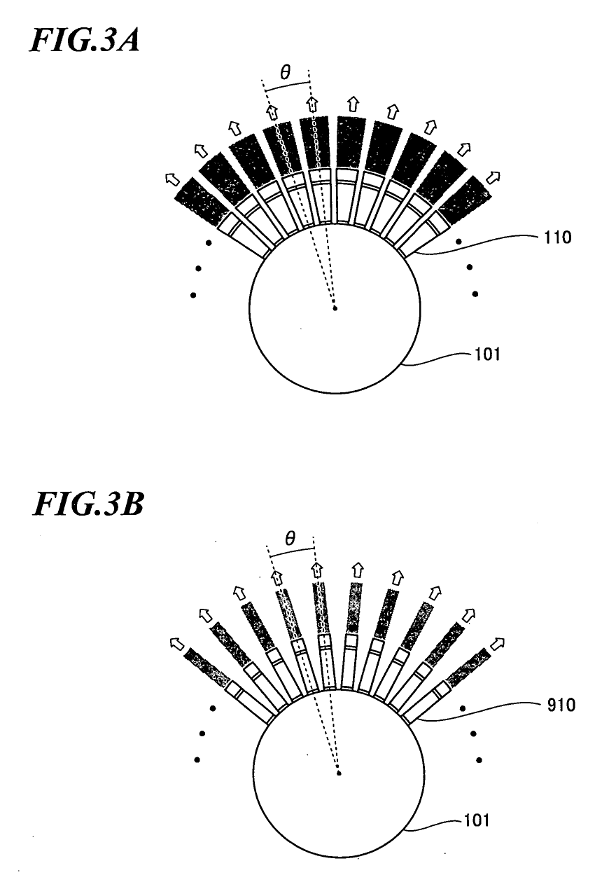

FIG. 3A shows a state in which ultrasonic wave US is transmitted from the ultrasonic transducer array according to the embodiment, and FIG. 3B shows a state in which ultrasonic wave US is transmitted from a conventional ultrasonic transducer array. As shown in FIG. 3A, in the case where each element 110 has a shape radially spreading from the lower surface (the backing material 101 side) toward the upper surface (ultrasonic wave transmission surface side), the ultrasonic wave US propagates so as to broadly spread toward surrounding space. Contrary, as shown in FIG. 3B, in the case where the areas of the lower surface and the upper surface of each element 910 are nearly equal, the spread of the ultrasonic wave US transmitted therefrom is not so large, and there is plenty of room in the propagation region of ultrasonic waves US transmitted from the adjacent elements 910. That is, as clearly seen by the comparison between FIGS. 3A and 3B, ultrasonic waves can be propagated in space around the ultrasonic transducer array more evenly in the case of the embodiment. In other words, ultrasonic wave information relating a larger number of regions can be obtained and ultrasonic images with higher resolution can be generated.

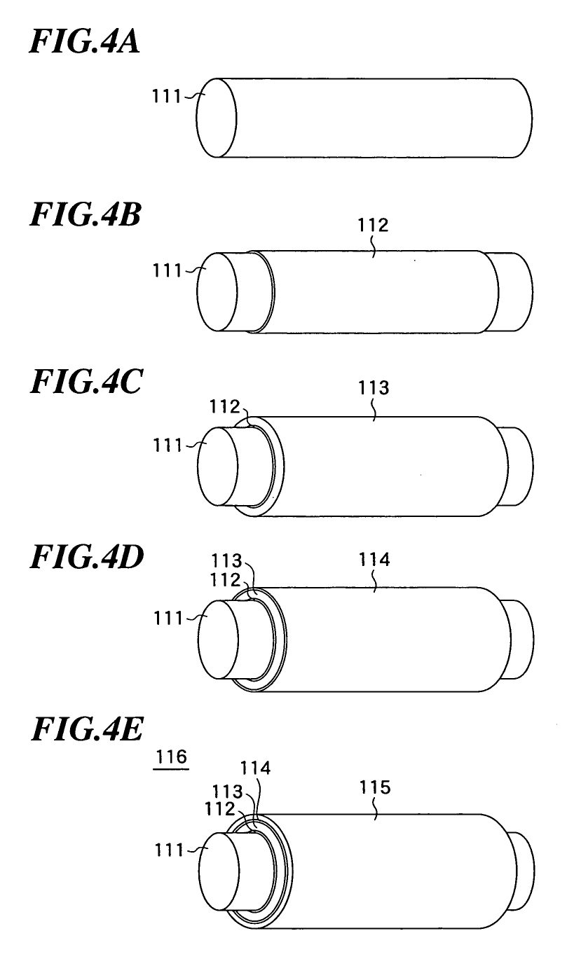

Next, a method of manufacturing the ultrasonic transducer array according to the embodiment will be described by referring to FIGS. 4A to 7C.

First, as shown in FIG. 4A, a substrate 111 having a curved surface is prepared. The curved surface becomes an element arrangement surface in a finished ultrasonic transducer array. In the embodiment, a cylindrical substrate 111 is used for fabricating a radial scan ultrasonic transducer array.

Further, the substrate 111 is not only used as a film formation substrate in a film formation process, which will be described later, but also a backing material (see FIGS. 1A to 1C) in the finished product. Accordingly, it is necessary to select as the substrate 111 a material having hardness that enables film formation and having a characteristic that easily absorbs ultrasonic waves. Further, it is also necessary to consider heat resistance in a heat treatment process, which will be described later. Accordingly, in the embodiment, a material consisting primarily of a polyimide resin is used as the substrate 111.

Then, as shown in FIG. 4B, a lower electrode layer 112 is formed by forming a film of a conducting material such as platinum in the cylinder side surface region of the substrate 111 by the sputtering method, plating method, or the like, for example. Here, the lower electrode layer 112 is used as an electrode in the finished product and also used as an anchor layer in the subsequent film formation process. That is, in the embodiment, subsequently, a piezoelectric material layer is formed by using a film forming method of causing a raw material powder to collide against the under layer, and a phenomenon that the raw material powder cuts into the under layer (called “anchoring”) simultaneously occurs. The thickness of the anchor layer (the layer into which the powder cuts) produced by the anchoring is different according to the material of the under layer (under electrode layer 112), the speed of the powder and so on, and the thickness normally becomes about 10 nm to about 300 nm. Therefore, in order to sufficiently produce anchoring to bring the piezoelectric material layer into close contact with the under layer and to sufficiently secure conductivity as an electrode, the thickness of the lower electrode layer 112 is desirably about 200 nm to about 300 nm or more. Further, as a material of the lower electrode layer 112, platinum is desirably used because platinum has high adhesiveness to the piezoelectric material layer and hardness with which the anchoring relatively easily occurs.

Then, as shown in FIG. 4C, a piezoelectric material layer 113 is formed on the surface of the lower electrode layer 112. In the embodiment, as the piezoelectric material layer 113, for example, a PZT film having a thickness of about 1 mm is formed by using the aerosol deposition (AD) method. One reason is that a film of ceramic such as PZT can be easily formed on a curved surface according to the AD method, as will be described later. Another reason is that the PZT film formed by the AD method is dense and strong and contains no impurities, and it has a possibility to improve the characteristics of elements.

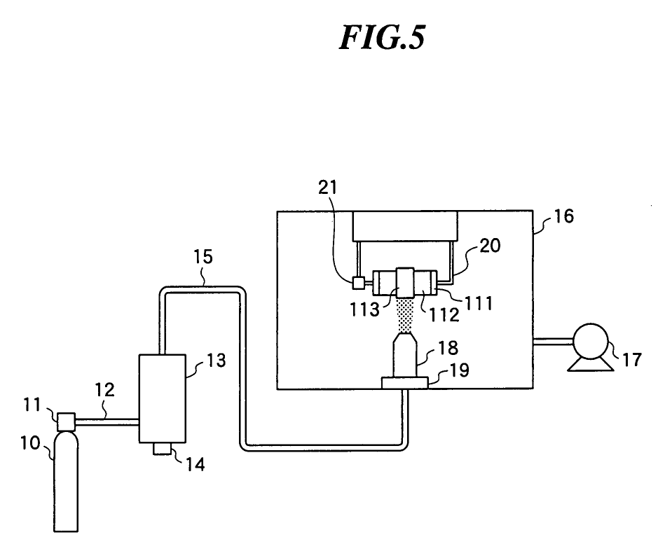

FIG. 5 is a schematic diagram showing a film forming device using the AD method. This film forming device includes a compressed gas cylinder 10 provided with a pressure regulating part 11, carrier pipes 12 and 15, an aerosol generating part 13, a container driving part 14, a film forming chamber 16 in which aerosol film formation is performed, an exhaust pump 17, a nozzle 18 disposed in the film forming chamber 16, a nozzle driving part 19, a supporting part 20 and a rotation driving part 21. The substrate 111 as a target of film formation is set in the supporting part 20.

The compressed gas cylinder 10 is filled with nitrogen (N₂) used as a carrier gas. As the carrier gas, oxygen (O₂), helium (He), argon (Ar), dry air, or the like may be used other than that.

The aerosol generating part 13 is a container in which a micro powder of a raw material as a film formation material is provided. By introducing the carrier gas via the carrier pipe 12 into the aerosol generating part 13, the raw material powder is blown up to generate an aerosol. In this regard, the concentration of aerosol or the like can be controlled by regulating the gas pressure by the pressure regulating part 11.

The container driving part 14 provides micro vibration or relatively slow motion to the aerosol generating part 13. Here, the raw material powder (primary particles) provided in the aerosol generating part 13 is agglomerated by the electrostatic force, Van der Waals force or the like as time passes and form agglomerated particles. Among them, giant particles of several micrometers to several millimeters are also large in mass and collect at the bottom of the container. If they collect near the exit of the carrier gas (near the exit of the carrier pipe 12), the primary particles can not be blown up by the carrier gas. Accordingly, in order not to allow the agglomerated particles to collect at one place, the container driving part 14 provides vibration or the like to the aerosol generating part 13 so as to agitate the powder provided within the generating part.

The exhaust pump 17 exhausts the air within the film forming chamber 16 so as to hold a predetermined degree of vacuum.

The nozzle 18 has an opening having a length of about 5 mm and a width of about 0.5 mm, for example, and sprays the aerosol supplied from the aerosol generating part 13 via the carrier pipe 15 from the opening toward the substrate 111 at a high speed. Further, the nozzle 18 is provided in the nozzle driving part 19. The nozzle driving part 19 displaces the opening of the nozzle 18 facing the substrate 111 by moving the nozzle 18 in a predetermined direction (the horizontal direction in FIG. 5).

The rotation driving part 21 changes the region (film formation region) facing the nozzle 18 on the substrate 111 by rotating the supporting part 20 that is supporting the substrate 111.

By providing a mechanism for driving either or both of the nozzle 18 and the supporting part 20, the distance between them (i.e., the gap between the opening of the nozzle 18 and the film formation region) may be adjusted.

Further, in FIG. 5, the supporting part 20 supports the substrate 111 through the center of the substrate 111, however, it may support the substrate 111 in any form as long as it can hold the substrate 111 in a rotatable condition. For example, it may sandwich the substrate 111 from both left and right sides in FIG. 5.

In such a film forming device, a PZT powder having an average particle diameter of 0.3 μm, for example, is placed in the aerosol generating part 13, and the device is driven. Thereby, an aerosol containing the PZT powder is sprayed from the nozzle 18 toward the substrate 111 and a PZT film is formed in a predetermined region on the substrate 111.

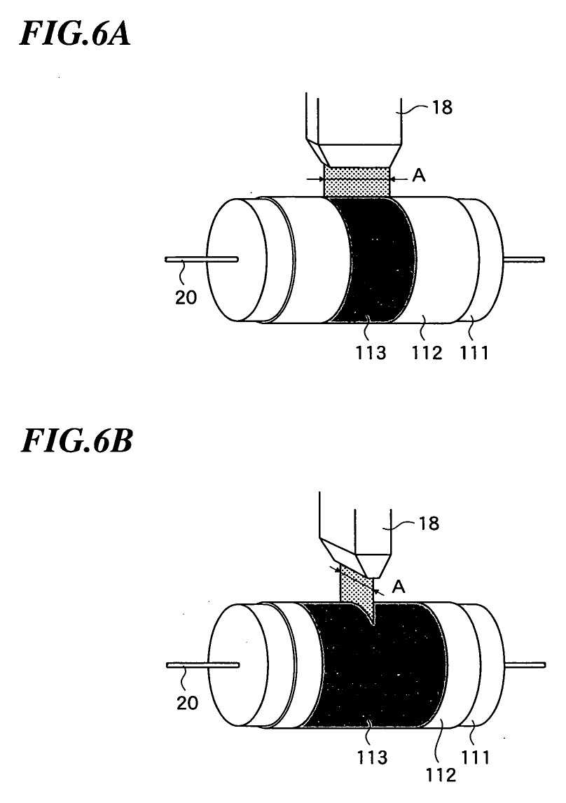

FIGS. 6A and 6B show positional relationships between the nozzle 18 and the substrate 111. As shown in FIG. 6A, the substrate 111 maybe oriented with the rotation axis thereof in parallel with the longitudinal side of the opening (opening width A) provided in the nozzle 18. In this case, the piezoelectric material layer 113 can be formed in width corresponding to the opening width around the substrate 111 by rotating the substrate 111. Further, as shown in FIG. 6B, the substrate 111 maybe oriented with the rotation axis thereof perpendicular to the opening width A. In this case, the piezoelectric material layer 113 can be formed around the substrate 111 by rotating the substrate 111 and moving the nozzle 18 in a direction perpendicular to the rotation axis of the substrate 111.

In the case shown in FIG. 6B, in place of movement of the nozzle 18, the substrate 111 may be shifted in parallel while being rotated. In this case, driving means for parallel shift of the supporting part in addition to the rotation driving part 21 may be provided to the film forming device shown in FIG. 5.

Then, the substrate 111 is detached from the supporting part 20, and a multilayered structure including the substrate 111 to the piezoelectric material layer 113 is heat-treated in an oxygen atmosphere at 400° C., for example. Thereby, the grain size of PZT crystal contained in the piezoelectric material layer 113 is made larger.

Then, as shown in FIG. 4D, an upper electrode layer 114 is formed by forming a film of a conducting material on the surface of the heat-treated piezoelectric material layer 113 by the sputtering method, plating method or the like, for example.

Furthermore, as shown in FIG. 4E, an acoustic matching layer 115 of glass or the like is formed on the surface of the upper electrode layer 114. The acoustic matching layer 115 may be formed by the AD method shown in FIG. 5, or formed by using a known film formation technology such as the evaporation method or the sputtering method. Thereby, a cylindrical multilayered structure 116 including the substrate 111 to the acoustic matching layer 115 is fabricated. The acoustic matching layer 115 may be formed by attaching a material of the acoustic matching layer formed of a sheet to the surface of the upper electrode layer 114. In this case, the material is desirably attached without using an adhesive in order to minimize the hindrance to the propagation efficiency of ultrasonic waves.

Further, subsequently, two end surfaces (bottom surfaces of the cylindrical shape) of the multilayered structure 116 are formed by grinding or cutting, and the two electrode layers 112 and 114 are desirably exposed on the end surfaces.

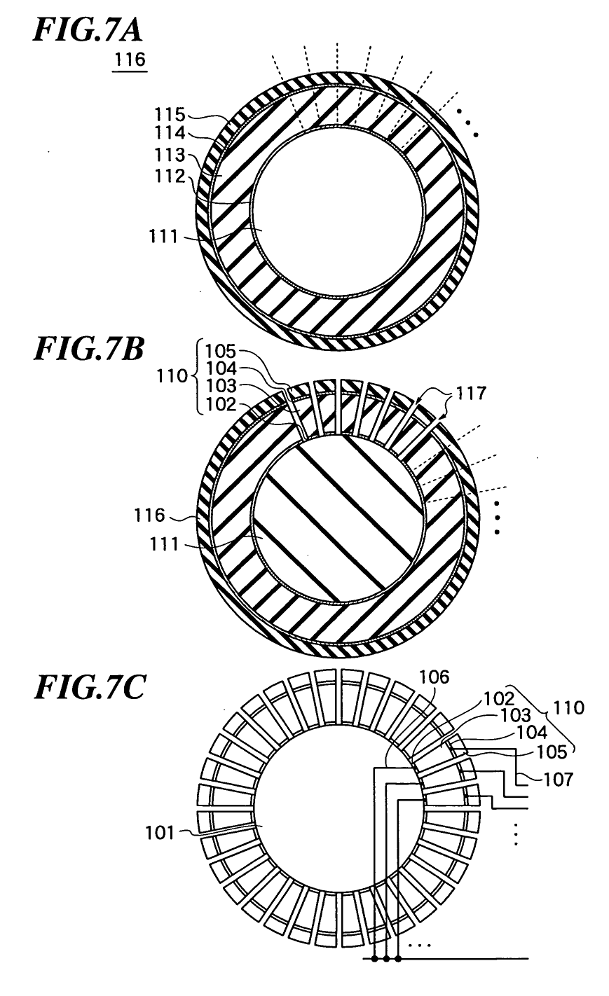

Then, grooves are formed in a region of the multilayered structure 116 shown by broken lines in FIG. 7A with predetermined pitches to the substrate 111 by dicing the multilayered structure 116 by using a precision cutting grinding wheel. Alternatively, the grooves may be formed by using the sand blasting method in place of dicing. Thereby, as shown in FIG. 7B, plural elements 110 arranged with predetermined pitches on the substrate 111 and spaced from one another by grooves 117 are formed. Furthermore, as shown in FIG. 7C, the wirings 106 and 107 are drawn from the lower electrode 102 and the upper electrode 104 included in each element 110, respectively. Thereby, the ultrasonic transducer array 100 shown in FIGS. 1A to 1C is completed.

As mentioned above, according to the embodiment, since plural elements arranged on a curved surface are fabricated by forming grooves in a multilayered structure having a cylindrical shape, large mechanical load is no longer placed thereon unlike the conventional manufacturing process of curving a planer substrate after plural elements are arranged on the substrate. Accordingly, the manufacture yield can be improved. Further, the plural elements can be accurately arranged at intervals according to processing widths of the precision cutting grinding wheel.

Although the case where one ultrasonic transducer array is fabricated has been described above, plural ultrasonic transducer array scan be fabricated by the same process. That is, a cylindrical multilayered structure (the substrate 111 to the acoustic matching layer 115) having a necessary length, e.g., ((a length of one ultrasonic transducer)×(a number of ultrasonic transducers to be fabricated)+α) may be fabricated and the cylindrical multilayered structure may be divided before the step of drawing wirings shown in FIG. 7C.

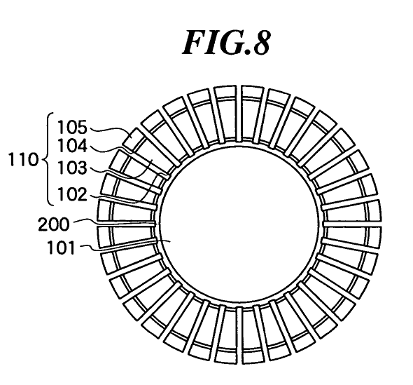

Next, an ultrasonic transducer array according to the second embodiment of the present invention will be described. FIG. 8 is a sectional view showing a configuration of the ultrasonic transducer array according to the embodiment.

As shown in FIG. 8, the ultrasonic transducer array according to the embodiment includes a backing material 101, plural elements 110, and an intermediate layer 200 provided between them. The materials, shapes, arrangements etc. of the backing material 101 and the plural elements 110 are the same as those in the first embodiment of the present invention.

The intermediate layer 200 is formed of a machinable material having hardness to some degree like machinable ceramics (a kind of ceramic of easy precision machining). Because, in the embodiment, the intermediate layer 200 is used as a dummy film formation substrate in the film forming process, which will be described later. Further, the acoustic impedance of the intermediate layer 200 is desirably relatively near that of the piezoelectric material 103 included in the element 110. This is for propagating the ultrasonic waves generated in the element 110 efficiently to the backing material 101.

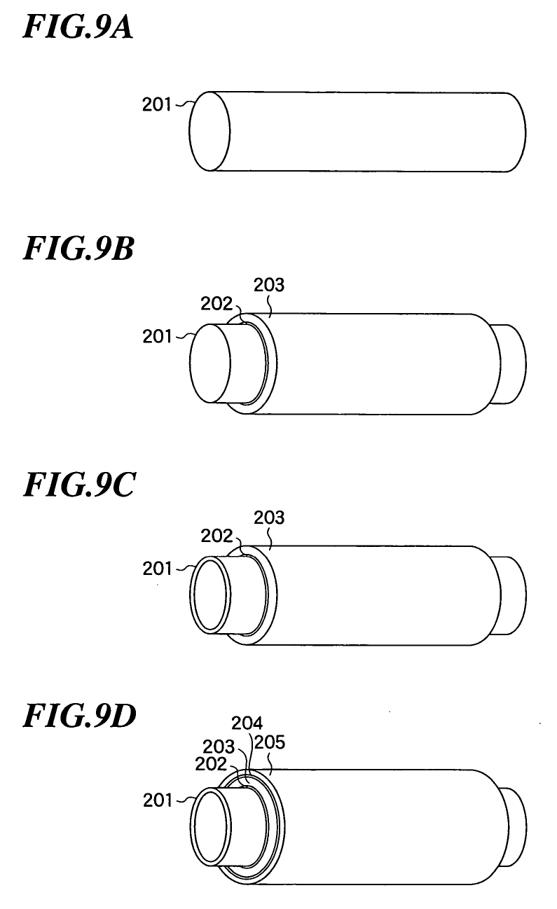

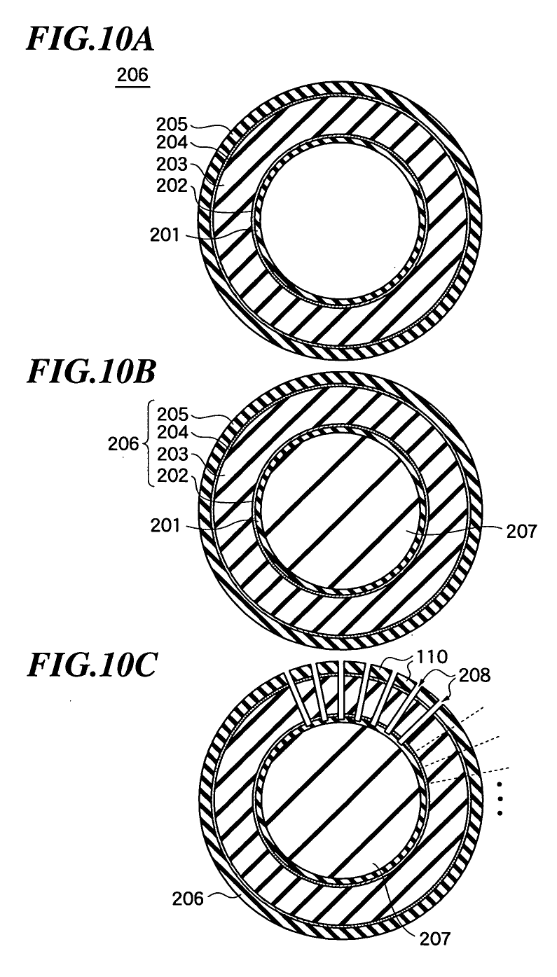

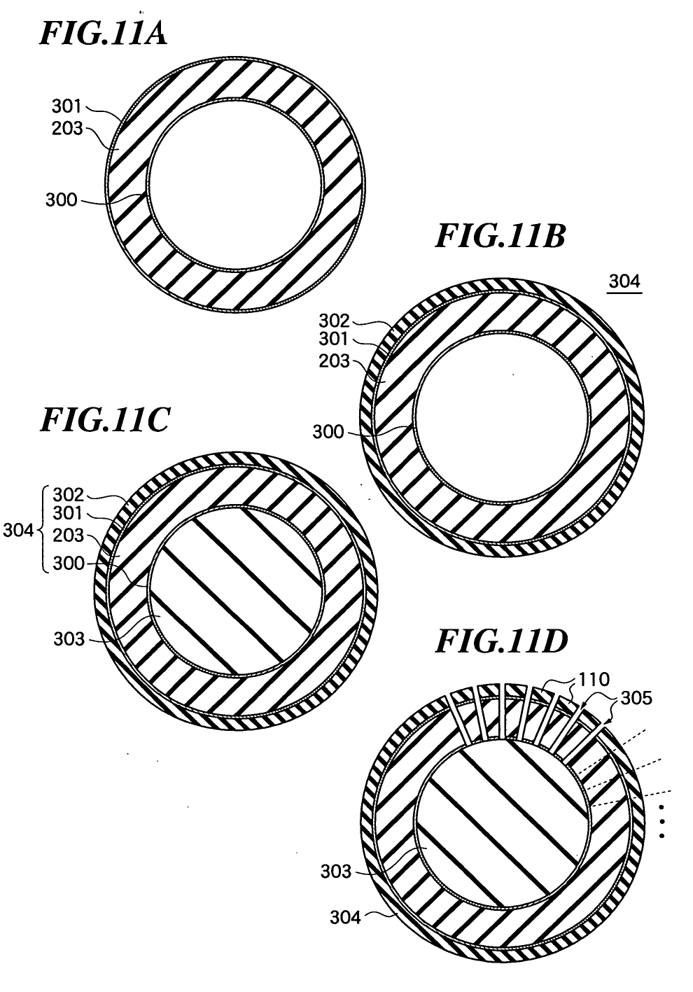

A method of manufacturing the ultrasonic transducer array according to the embodiment will be described by referring to FIGS. 9A to 10C.

First, as shown in FIG. 9A, a substrate 201 formed of Macor (registered trademark) as a kind of machinable ceramics and having a cylindrical shape is prepared. Then, as shown in FIG. 9B, a lower electrode layer 202 and a piezoelectric material layer 203 are sequentially formed on the surface of the substrate 201. The method of forming these layers is the same as that has been described by referring to FIGS. 4B and 4C in the first embodiment of the present invention.

Then, as shown in FIG. 9C, the substrate 201 is made to have a tubular shape by hollowing out the interior of the substrate 201. In this regard, a known machining method such as cutting work, grinding, or fusing can be used. In the embodiment, cutting work is performed because Macor (registered trademark) is used as the substrate 201. The hollowing may be performed after the heat treatment process or formation of an upper electrode layer 204 and an acoustic matching layer 205, which will be described later.

Subsequently, the substrate 201 to the piezoelectric material layer 203 are heat-treated in an oxygen atmosphere at 400° C., for example. Thereby, the grain size of PZT crystal contained in the piezoelectric material layer 203 is made larger. Further, since ceramic is used as the substrate 201, heat treatment can be performed at higher temperature.

Then, as shown in FIG. 9D, an upper electrode layer 204 and an acoustic matching layer 205 are sequentially formed on the surface of the heat-treated piezoelectric material layer 203. The method of forming these layers is the same as that has been described by referring to FIGS. 4D and 4E in the first embodiment of the present invention. Thereby, as shown in FIG. 10A, a cylindrical multilayered structure 206 is fabricated.

Then, as shown in FIG. 10B, the interior of the cylindrical multilayered structure 206 is filled with a backing material 207, and the material is cured. As the backing material 207, a polyimide resin, epoxy resin, rubber, and a material containing at least one of those can be used. Thus, in the case of filling with the backing material 207 after heat treatment of the piezoelectric material layer 203, it is not so much necessary to consider the heat resistance of the backing material, and therefore, the range of material choices can be expanded. The filling with the backing material 206 may be performed after the heat treatment and before formation of the upper electrode layer 204.

Then, as shown in FIG. 10C, grooves 208 are formed in a region of the multilayered structure 206, which has been filled with the baking material 207, shown by broken lines with predetermined pitches to the substrate 201 by dicing etc. Thereby, the plural elements 110 arranged on the substrate 201 (i.e., the intermediate layer 200 shown in FIG. 8) and spaced from one another by the grooves 208 with predetermined pitches are formed. Furthermore, the ultrasonic transducer array is completed by drawing wirings from the lower electrode and the upper electrode of each element 110.

As mentioned above, in the embodiment, since the material having appropriate hardness like ceramic is used as a film formation substrate, when the piezoelectric material layer is formed by the AD method, the film formation efficiency can be made higher. In this regard, a material having acoustic impedance relatively near that of the piezoelectric material layer is selected as the film formation substrate, and thereby, even if the film formation substrate is left in the finished product, the vibration generated in the piezoelectric material layer is no longer prevented from propagating to the backing material.

In the embodiment, the interior of the cylinder is hollowed after the film formation by the AD method is performed on the substrate having a cylindrical shape, however, a substrate that has been formed in a tubular shape in advance may be used.

Next, a method of manufacturing the ultrasonic transducer array according to the third embodiment of the present invention will be described by referring to FIGS. 9A to 9D and FIGS. 11A to 11D.

First, as described by referring to FIGS. 9A and 9B in the second embodiment of the present invention, a lower electrode layer 202 and a piezoelectric material layer 203 are formed on the surface of a substrate 201 of Macor (registered trademark). Then, the substrate 201 is hollowed from inside and then ground, and thereby, the substrate 201 is removed and the end surface of the piezoelectric material layer 203 is exposed. Then, the remaining cylindrical piezoelectric material layer 203 is heat-treated in an oxygen atmosphere at 400° C., for example. In the embodiment, since the lower electrode layer 202 is only used as an anchor layer when the piezoelectric material layer 203 is formed by the AD method, it may be peeled together when the substrate 201 is removed.

Then, as shown in FIG. 11A, a lower electrode layer 300 and an upper electrode layer 301 are formed by forming films of a conductive material at the inner side and outer side of the heat-treated cylindrical piezoelectric material layer 203, respectively, by the sputtering method, plating method, or the like. Then, as shown in FIG. 11B, a multilayered structure 304 having a circular cylindrical shape is fabricated by forming an acoustic matching layer 302 on the surface of the upper electrode layer 301. Furthermore, as shown in FIG. 11C, the interior of the lower electrode layer 300 is filled with a backing material 303, and the material is cured. Then, as shown in FIG. 11D, grooves 305 are formed in a region of the multilayered structure 304, which has been filled with the backing material 303, shown by broken lines with predetermined pitches to the backing material 303 by dicing using a precision cutting grinding wheel. Thereby, the plural elements 110 arranged on the backing material 303 and spaced from one another by the grooves 305 with predetermined pitches are formed. Furthermore, the ultrasonic transducer array shown in FIGS. 1A to 1C is completed by drawing wirings from the lower electrode and the upper electrode of each element 110.

As mentioned above, in the embodiment, since the material having appropriate hardness like ceramic is used as a substrate, film formation efficiency can be made higher when the piezoelectric material layer is formed by the AD method. Further, since the heat treatment of the piezoelectric material layer is performed after the substrate used in the film formation process is removed, the breakage of the piezoelectric material layer due to heat distortion generated between the substrate and the piezoelectric material layer can be prevented.

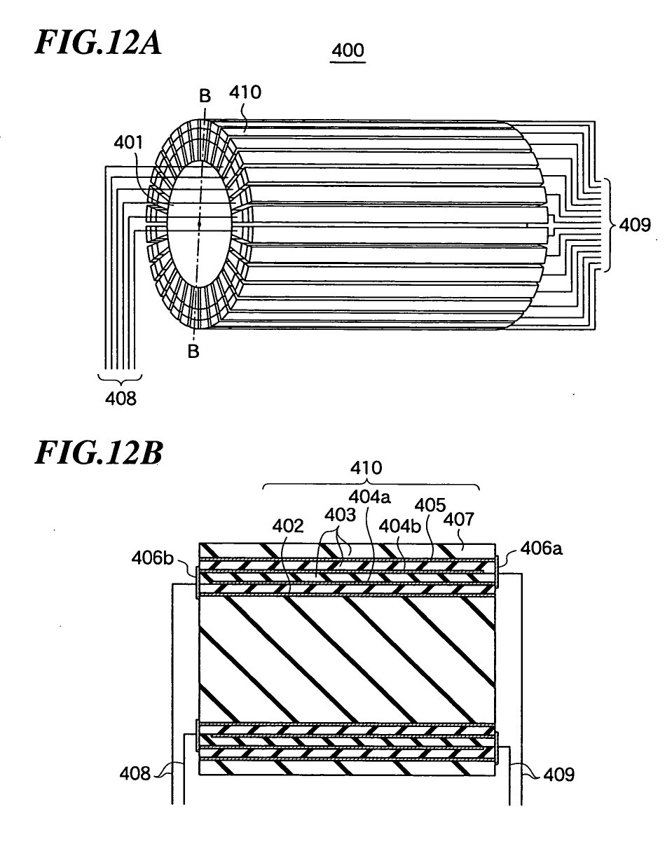

Next, an ultrasonic transducer array according to the fourth embodiment of the present invention will be described by referring to FIGS. 12A and 12B.

As shown in FIG. 12A, the ultrasonic transducer array 400 according to the embodiment includes a backing material 401 formed in a cylinder shape and plural elements 410 arranged on the cylinder side surface of the backing material 401. The shapes and sizes of the ultrasonic transducer array 400 and the respective elements 410 are substantially the same as those in the first embodiment of the present invention.

FIG. 12B shows a section of the ultrasonic transducer array along B-B shown in FIG. 12A.

As shown in FIG. 12B, each element 410 includes a lower electrode layer 402, plural piezoelectric material layers 403, and internal electrode layers 404a and 404b provided between the plural piezoelectric material layers 403, and an upper electrode layer 405. Further, side electrodes 406a and 406b are formed on end surfaces of each element 410. Wirings 408 and 409 are drawn from these side electrodes 406a and 406b, respectively. Furthermore, each element 410 may include an acoustic matching layer 407.

Each of the internal electrode layers 404a and 404b is provided so as to extend to only one side surface of two opposed side surfaces (the right side surface and the left side surface in FIG. 12B) of the element 410. Thereby, the side electrode 406a is electrically connected to the internal electrode layer 404a and the upper electrode layer 405, and insulated from the internal electrode layer 404b and the lower electrode layer 402. Further, the side electrode 406b is electrically connected to the internal electrode layer 404b and the lower electrode layer 402, and insulated from the internal electrode layer 404a and the upper electrode layer 405. By thus arranging the electrode layers and side electrodes, stacked plural layers are electrically connected in parallel. Since the areas of the opposed electrodes can be further increased in a structure having such a laminated structure compared to those of a single-layer structure, the electric impedance can be reduced. Therefore, the structure operates more efficiently for the applied voltage compared to a single-layer structure, and the structure can efficiently transmit ultrasonic waves by a drive signal with low intensity and improve the reception sensitivity of ultrasonic waves. In the embodiment, each one of the internal electrode layers 404a and 404b is provided to form a three-layer piezoelectric material layers 403, however, pluralities of the internal electrode layers 404a and 404b may be provided and the number of stacked layers of the piezoelectric material layers 403 may be increased.

Here, the insulating region provided for insulating the internal electrode layer 404a from the side electrode 406b and the insulating region provided for insulating the internal electrode layer 404b from the side electrode 406a do not expand or contract when a voltage is applied to the element 410. Accordingly, there is a possibility that stress concentrates on the regions and they become easy to break. However, in the case where the length of the entire element is longer (i.e., 20 mm) than the width of the insulating region (i.e., 50 μm) as in the embodiment, it is considered that the stress concentration does not greatly affect on the performance of the elements.

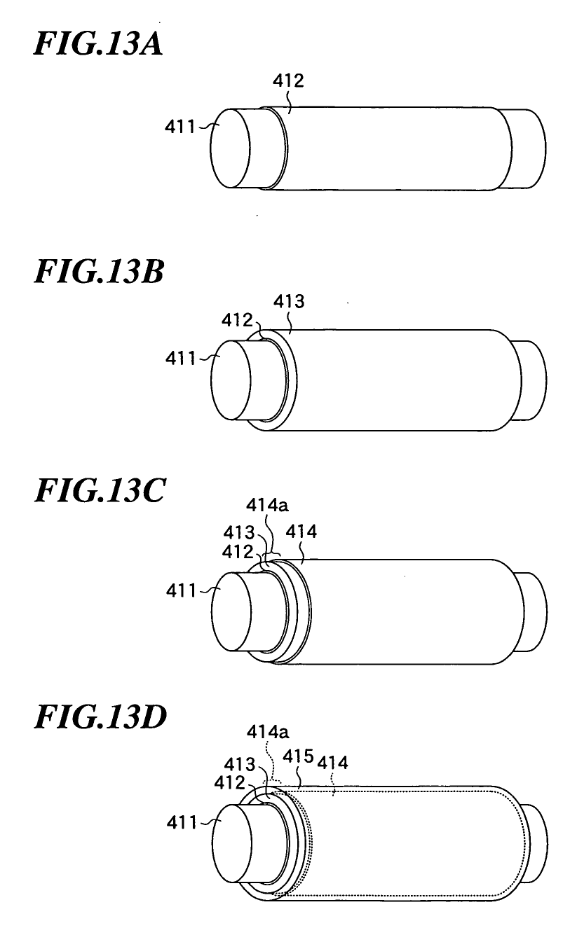

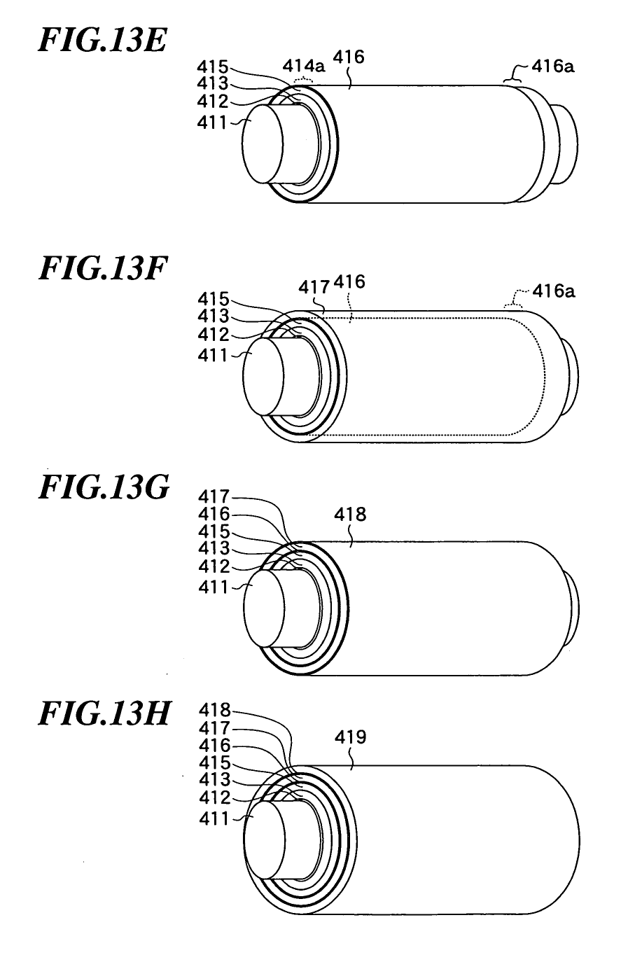

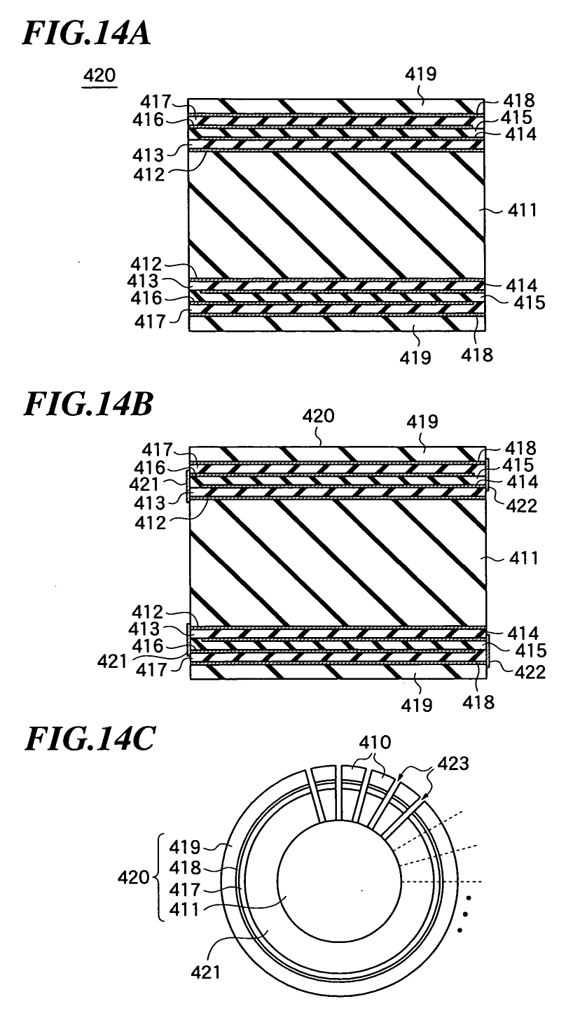

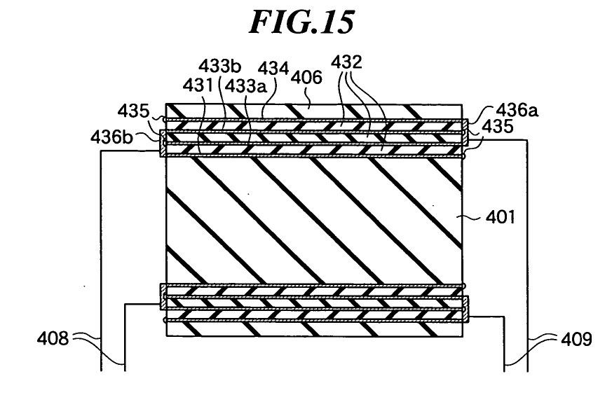

Next, a method of manufacturing the ultrasonic transducer array according to the embodiment will be described by referring to FIGS. 13A to 14C.

First, as shown in FIG. 13A, a substrate 411 formed of a material used as a backing material like a polyimide resin and having a cylindrical shape is prepared, and a lower electrode layer 412 is formed in the cylinder side surface region thereof by forming a film of a conducting material such as platinum by the sputtering method or the like.

Then, as shown in FIG. 13B, a piezoelectric material layer 413 is formed on the surface of the lower electrode layer 412 by the AD method.

Then, as shown in FIG. 13C, an internal electrode layer 414 is formed in a region except for an insulating region 414a provided on one end of the surface of the piezoelectric material layer 413. Furthermore, as shown in FIG. 13D, a piezoelectric material layer 413 is formed on the surface of the internal electrode layer 414 and the insulating region 414a.

Then, as shown in FIG. 13E, an internal electrode layer 416 is formed in a region except an insulating region 416a provided on the opposite end to that of the insulating region 414 of the surface of the piezoelectric material layer 415. Furthermore, as shown in FIG. 13F, a piezoelectric material layer 417 is formed on the surface of the internal electrode layer 416 and the insulating region 416a.

Subsequently, if necessary, the steps shown in FIGS. 13C to 13F are repeated at the desired number of times. Furthermore, the multilayered structure including the substrate 411 to the piezoelectric material layer 417 is heat-treated in an oxygen atmosphere at 400° C., for example.

Then, as shown in FIG. 13G, an upper electrode layer 418 is formed on the surface of the heat-treated piezoelectric material layer 417, and, as shown in FIG. 13H, an acoustic matching layer 419 is formed thereon. Thereby, a cylindrical multilayered structure 420 having a multilayered structure as shown in FIG. 14A is formed.

Then, as shown in FIG. 14B, side electrodes 421 and 422 are formed on two end surfaces of the multilayered structure 420. In this regard, the side electrode 421 is provided so as to be connected to the lower electrode layer 412 and insulated from the upper electrode layer 417 on one side surface (on the left side of the drawing). Further, the side electrode 422 is provided so as to be connected to the upper electrode layer 418 and insulated from the lower electrode layer 412 on the opposite side surface (on the right side of the drawing).

Then, as shown in FIG. 14C, grooves 423 are formed with predetermined pitches in a region of the multilayered structure 420 shown by broken lines, in which the side electrodes 421 and 422 have been formed, as far as the substrate 411 by dicing or the like. Thereby, the plural elements 410 arranged on the substrate 411 in with predetermined pitches are formed. Furthermore, the ultrasonic transducer array is completed by drawing wirings from the lower electrode layer and the upper electrode layer of each element 410.

In the above-mentioned embodiment, the substrate 411 used at the time of film formation is used as the backing material 401 in the completed ultrasonic transducer array without change. However, as mentioned in the second or third embodiment of the present invention, film formation may be performed by employing machinable ceramics or the like as a substrate, a part or the entire of the substrate may be removed before heat treatment of the piezoelectric material layers and filling of a backing material may be performed after heat treatment.

FIG. 15 is a sectional view showing a modified example of the ultrasonic transducer array according to the fourth embodiment of the present invention. Each of the plural elements included in the ultrasonic transducer array includes a lower electrode layer 431, plural piezoelectric material layers 432, internal electrode layers 433a and 433b, an upper electrode layer 434, insulating films 435, and side electrodes 436a and 436b in place of the lower electrode layer 402 to the upper electrode layer 405 and the side electrodes 406a and 406b shown in FIGS. 1A to 1C. In the ultrasonic transducer array shown in FIGS. 12A and 12B, the internal electrode layers are insulated from the side electrodes by providing insulating regions within the internal electrode layers. Contrary, in FIG. 15, the internal electrode layers 433a and 433b are formed to extend to two end surfaces of the element and the insulating film 435 is formed on selected one of the two ends of each internal electrode layer exposed on the end surfaces of the element. Thereby, the internal electrode layer 433a is connected to the side electrode 436a and insulated from the side electrode 436b by the insulating film 435. Further, the internal electrode layer 433b is connected to the side electrode 436b and insulated from the side electrode 436a by the insulating film 435. The lower electrode layer 431 and the upper electrode layer 434 may be insulated from the side electrodes 436a and 436b, respectively, by forming insulating films 435 on the end surfaces.

In the case where such an ultrasonic transducer array is fabricated, in FIGS. 13C to 13F, the internal electrode layers 414 and 416 are formed on the entire surface of the piezoelectric material layers 431 and 415, respectively. Then, before the side electrodes 421 and 422 shown in FIGS. 14B and 14C are formed, insulating films are formed on predetermined end surfaces of the internal electrode layers exposed on the end surfaces of the multilayered structure. The insulating film can be formed by covering the end surfaces of the internal electrode layers with glass using electrophoresis, for example.

In the case where the respective electrode layers are formed as shown in FIG. 15, unlike the case where insulating regions are provided within the layers, not only the stress concentration on part of the piezoelectric material layers is prevented but also plural ultrasonic transducer arrays can be efficiently fabricated. That is, without considering how to form the pattern of internal electrode layers, a cylindrical multilayered structure having a necessary length, e.g., (a length of one ultrasonic transducer)×(a number of ultrasonic transducers to be fabricated)+α) may be fabricated and divided into plural pieces, and then, insulting films and side electrodes may be formed on the exposed end surfaces.

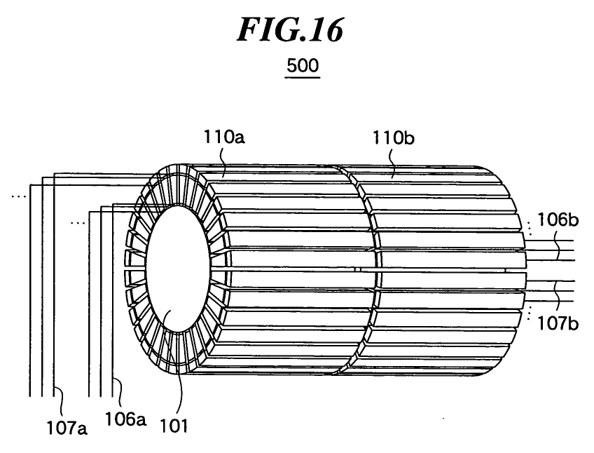

Next, an ultrasonic transducer array according to the fifth embodiment of the present invention will be described by referring to FIG. 16.

As shown in FIG. 16, an ultrasonic transducer array 500 according to the embodiment includes a backing material 101 and plural elements 110a and 110b arranged in a two-dimensional manner on the cylinder side surface of the backing material 101. The structures of the respective elements 110a and 110b are the same as those of the elements 110 shown in FIGS. 1A to 1C. Further, wirings 106a and 107a are drawn from each of the plural elements 110a on one end surface (at the left side in FIG. 16) of the ultrasonic transducer array 500. On the other hand, wirings 106b and 107b are drawn from each of the plural elements 110b on the other end surface (at the right side in FIG. 16) of the ultrasonic transducer array 500.

The ultrasonic transducer array according to the embodiment can be fabricated, at the step of forming grooves 117 in the cylindrical multilayered structure 116 shown in FIG. 7B, by additionally forming another groove as far as the backing material 111 in a direction different from that of the grooves 117 (e.g., in a direction perpendicular to the grooves 117), for example.

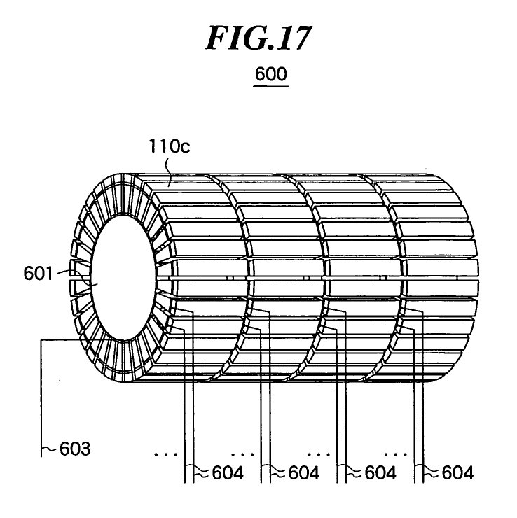

Next, an ultrasonic transducer array according to the sixth embodiment of the present invention will be described by referring to FIG. 17.

As shown in FIG. 17, an ultrasonic transducer array 600 according to the embodiment includes a backing material 601 having a cylindrical shape and plural elements 110c arranged in a two-dimensional manner on the cylinder side surface of the backing material 601. The structures of the respective plural elements 110c are the same as those of the elements 110 shown in FIGS. 1A to 1C.

The ultrasonic transducer array according to the embodiment can be fabricated, at the step of forming grooves 117 in the cylindrical multilayered structure 116 shown in FIG. 7B, by additionally forming other plural grooves as far as the backing material 111 in a direction different from that of the grooves 117 (e.g., in a direction perpendicular to the grooves 117), for example.

Alternatively, after the grooves 117 are formed in the cylindrical multilayered structure 116, the multilayered structure 116 is sliced in a direction different from that of the grooves 117 (e.g., in a direction perpendicular to the grooves 117) so that plural disk-shaped ultrasonic transducer arrays are fabricated. Then, wiring boards are provided on the end surfaces of the respective disk-shaped ultrasonic transducer arrays, and those disk-shaped ultrasonic transducer arrays may be bonded at the part of the backing material, which is located at the center, by using an adhesive or the like.

In the embodiment, since it is considered to be difficult to draw the wirings of the elements 110c provided inside, common wirings are desirably provided. The method of forming wirings will be described later in detail.

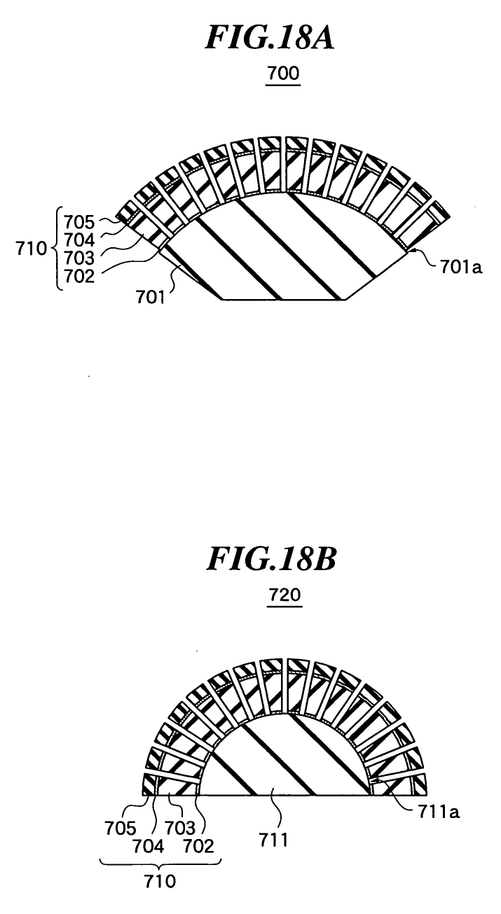

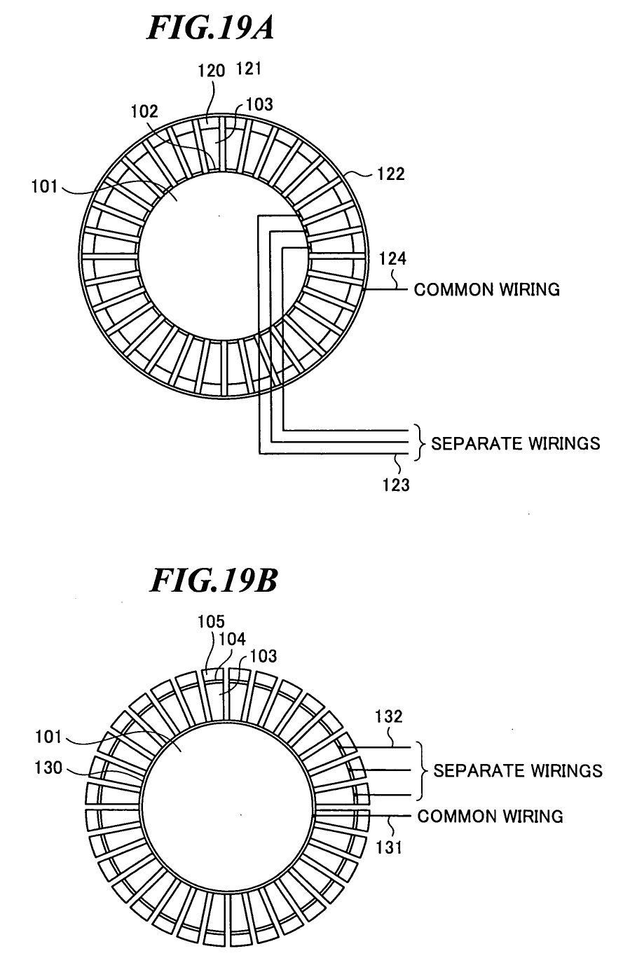

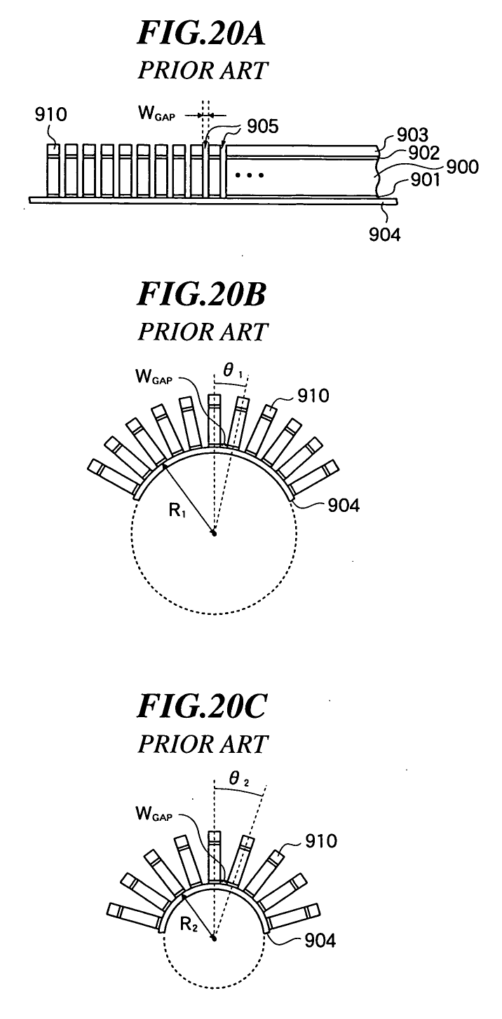

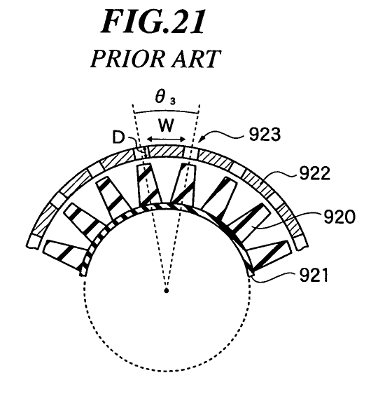

Next, an ultrasonic transducer array according to the seventh embodiment of the present invention will be described by referring to FIGS. 18A and 18B.

An ultrasonic transducer array 700 shown in FIG. 18A is an array of a convex type including a backing material 701 having an element arrangement surface 701a, which is curved, and plural elements 710 arranged on the element arrangement surface 701a of the backing material 701. Each of the plural elements 710 includes a lower electrode 702, a piezoelectric material 703, and an upper electrode 704. Further, each element may include an acoustic matching layer 705. The materials and functions of these parts 702 to 705 are the same as those of the lower electrode 102 to the acoustic matching layer 105 shown in FIGS. 1A to 1C. In FIGS. 18A and 18B, the wirings drawn from the lower electrode 702 and the upper electrode 704 are omitted.

Such an ultrasonic transducer array 700 can be fabricated in the following manner. That is, using the backing material 701 as a substrate, on the surface of the element arrangement surface 701a, the lower electrode layer, the piezoelectric material layer, the upper electrode layer, and the acoustic matching layer are sequentially formed according to a film forming method. Then, grooves are formed in the multilayered structure with predetermined pitches as far as the backing material 701 by dicing, etc. Thereby, plural elements 710 arranged on the backing material 701 and spaced from one another by the grooves with predetermined pitches are formed.

Further, the ultrasonic transducer array 720 shown in FIG. 18B includes a backing material 721 having a half columnar shape and plural elements 710 arranged on the element arrangement surface 721a of the backing material 701.

Thus, not only in an ultrasonic transducer array having a cylindrical shape but also in an ultrasonic transducer array of a convex type, plural elements can be arranged on a curved surface having a desired curvature easily with high yield.

In the above-mentioned first to seventh embodiments, in each of the plural elements included in the ultrasonic transducer array, the upper electrode layer and the acoustic matching layer have been provided on the surface of the piezoelectric material layer. However, the upper electrode layer may be omitted by forming the acoustic matching layer with an acoustic material having conductivity. In this case, the manufacturing process can be simplified. As the conductive acoustic material which can be used as the acoustic matching layer, an epoxy resin doped with an inorganic material such as metal, graphite, etc. can be cited.

Further, in the first to seventh embodiments, both lower electrode and upper electrode have been separately provided in each of the plural elements included in the ultrasonic transducer array. However, one of those electrodes may be made in common among plural elements.

FIG. 19A shows an example with the upper electrode of each element in common. The ultrasonic transducer array shown in FIG. 19A includes a backing material 101, plural elements including lower electrodes 102 and piezoelectric materials 103, acoustic matching layers 120 having conductivity, resin materials provided between adjacent elements, and a conducting film 122 continuously provided on the top of the plural elements. Separate wirings 123 are drawn from the lower electrodes 102 of the respective elements and a common wiring 124 is drawn from the conducting film 122. The shapes and materials of the backing material 101, the lower electrodes 102, and the piezoelectric materials 103 are the same as those in FIGS. 1A to 1C. Further, the resin material 121 insulates adjacent two elements from each other. Although the resin material 121 is provided to the height of the acoustic matching layer 120 in FIG. 19A, it is sufficient to provide the resin at least to the height of the adjacent piezoelectric material 103.

The acoustic matching layer 120 having conductivity has a function as an upper electrode in each element in addition to a function as an acoustic matching layer. As a material of the acoustic matching layer 120 having conductivity, the above-mentioned epoxy resin doped with an inorganic material such as metal, graphite, etc. can be used.

The conducting film 122 electrically connects the acoustic matching layers 120 having conductivity formed in the plural elements to one another. The conducting film 122 may be formed by forming a film of a conductive resin material or attaching the conductive resin material to the acoustic matching layers 120 or forming a film of metal such as platinum, an alloy or graphite. As a resin material which can be used as the conducting film 122, a material having conductivity and good acoustic matching with the acoustic matching layer 120 like an epoxy resin doped with an inorganic material such as metal is desirably selected.

In the case where graphite is used as the acoustic matching layer 120, in place of providing the conducting film 122 on the surface of the acoustic matching layers 120, resin materials having conductivity may be provided between adjacent acoustic matching layers 120. In this case, as the resin material having conductivity, a material that easily absorbs ultrasonic waves like an epoxy resin doped with an inorganic material such as metal is desirably selected. Further, in order to improve the acoustic matching with the object, another acoustic matching layer may be further formed on the outermost circumference. The outermost acoustic matching layer may be an insulating material, and, for example, an epoxy resin or plastic material can be used.

FIG. 19B shows an example with the lower electrode of each element in common. The ultrasonic transducer array shown in FIG. 19B includes a backing material 101, a common electrode 130, plural elements including piezoelectric materials 103, upper electrodes 104 and acoustic matching layers 105. The shapes and materials of the backing material 101, the lower electrodes 102, and the piezoelectric materials 103 are the same as those in FIGS. 1A to 1C.

A common wiring 131 is drawn from the common electrode 130 that has been continuously formed at the lower part of the plural elements and separate wirings 132 are drawn from the upper electrodes 104 provided in the respective elements. Such a common electrode 130 can be formed, for example, in FIG. 7B, not by providing grooves to the backing material 101 by dicing or the like, but by providing grooves to the surface of the lower electrode layer 112 or to the middle of the lower electrode layer 112. Alternatively, the entire backing material or the surface layer part thereof may be formed of a resin having conductivity or the like. As such a material, for example, a material fabricated by blending a conducting powder such as a tungsten powder and an epoxy resin can be cited.

Alternatively, as in the second or third embodiment of the present invention, in the case where a part or the entire of the substrate used at the time of film formation is removed, there is conceivable a method of drawing wirings by forming a common electrode or predetermined wiring pattern inside of the cylinder before filling the interior of the cylindrical multilayered structure with the backing material. Further, a cylindrical or circular cylindrical backing material with a predetermined wiring pattern formed may have been fabricated in advance, and the material may be provided inside of the multilayered structure. In this case, a desired wiring pattern can be relatively easily formed by the sputtering method or the like. In either method, plural elements are formed by forming grooves in the laminated structure formed on the side region of the substrate, the arrangement of elements are fixed by filling the space between those elements with a resin or the like, and then, the substrate is hollowed.

1. A method of manufacturing an ultrasonic transducer array including plural ultrasonic transducers arranged on a curved surface, said method comprising the steps of:
(a) preparing a substrate having a curved surface;
(b) forming a first conducting material layer on the curved surface of said substrate;
(c) forming a piezoelectric material layer on said first conducting material layer;
(d) forming a second conducting material layer on said piezoelectric material layer; and
(e) forming plural grooves having predetermined widths with predetermined pitches in a multilayered structure including said first conducting material layer, said piezoelectric material layer and said second conducting material layer formed at steps (b) to (d) so as to form said plural ultrasonic transducers.

2. A method of manufacturing an ultrasonic transducer array according to claim 1, further comprising the step of:
(d′) forming an acoustic matching layer on a surface of said second conducting material layer formed at step (d);
wherein step (e) includes forming plural grooves in a multilayered structure including said first conducting material layer, said piezoelectric material layer, said second conducting material layer and said acoustic matching layer formed at steps (b) to (d′).

3. A method of manufacturing an ultrasonic transducer array including plural ultrasonic transducers arranged on a curved surface, said method comprising the steps of:
(a) preparing a substrate having a curved surface;
(b) forming a first conducting material layer on the curved surface of said substrate;
(c) alternately stacking plural piezoelectric material layers and at least one internal electrode layer on said first conducting material layer;
(d) forming a second conducting material layer on an uppermost one of said plural piezoelectric material layers; and
(e) forming plural grooves having predetermined widths with predetermined pitches in a multilayered structure including said first conducting material layer, said plural piezoelectric material layers, said at least one internal electrode layer and said second conducting material layer formed at steps (b) to (d) so as to form said plural ultrasonic transducers.

4. A method of manufacturing an ultrasonic transducer array according to claim 3, further comprising the step of:
(d′) forming an acoustic matching layer on said second conducting material layer formed at step (d);
wherein step (e) includes forming plural grooves in a multilayered structure including said first conducting material layer, said plural piezoelectric material layers, said at least one internal electrode layer, said second conducting material layer and said acoustic matching layer formed at steps (b) to (d′).

5. A method of manufacturing an ultrasonic transducer array according to claim 1, wherein step (d) includes forming the second conducting material layer serving as an acoustic matching layer.

6. A method of manufacturing an ultrasonic transducer array according to claim 3, wherein step (d) includes forming the second conducting material layer serving as an acoustic matching layer.

7. A method of manufacturing an ultrasonic transducer array according to claim 1, wherein step (c) includes forming said piezoelectric material layer by using an aerosol deposition method of spraying an aerosol containing a piezoelectric material powder toward said substrate to deposit said piezoelectric material powder thereon.

8. A method of manufacturing an ultrasonic transducer array according to claim 3, wherein step (c) includes forming said plural piezoelectric material layers by using an aerosol deposition method of spraying an aerosol containing a piezoelectric material powder toward said substrate to deposit said piezoelectric material powder thereon.

9. A method of manufacturing an ultrasonic transducer array according to claim 7, further comprising the step of:
heat-treating said piezoelectric material layer formed at step (c).

10. A method of manufacturing an ultrasonic transducer array according to claim 8, further comprising the step of:
heat-treating said plural piezoelectric material layers formed at step (c).

11. A method of manufacturing an ultrasonic transducer array according to claim 2, wherein step (d′) includes forming said acoustic matching layer by using an aerosol deposition method of spraying an aerosol containing a material powder of the acoustic matching layer toward said substrate to deposit the material powder thereon.

12. A method of manufacturing an ultrasonic transducer array according to claim 4, wherein step (d′) includes forming said acoustic matching layer by using an aerosol deposition method of spraying an aerosol containing a material powder of the acoustic matching layer toward said substrate to deposit the material powder thereon.

13. A method of manufacturing an ultrasonic transducer array according to claim 1, wherein step (a) includes preparing the substrate serving as a backing material.

14. A method of manufacturing an ultrasonic transducer array according to claim 3, wherein step (a) includes preparing the substrate serving as a backing material.

15. A method of manufacturing an ultrasonic transducer array according to claim 1, further comprising the step of:
removing a part of said substrate and providing a backing material to the part of said substrate after step (c).

16. A method of manufacturing an ultrasonic transducer array according to claim 3, further comprising the step of:
removing a part of said substrate and providing a backing material to the part of said substrate after step (c).

17. A method of manufacturing an ultrasonic transducer array according to claim 1, further comprising the steps of:
(f) exposing one surface of said piezoelectric material layer by removing said substrate after step (c);
(g) forming a third conducting material layer on the surface of said piezoelectric material layer exposed at step (f); and
(h) providing a backing material on the third conducting material layer formed at step (g).

18. A method of manufacturing an ultrasonic transducer array according to claim 3, further comprising steps of:
(f) exposing one surface of one of said plural piezoelectric material layers by removing said substrate after step (c);
(g) forming a third conducting material layer on the surface of the piezoelectric material layer exposed at step (f); and
(h) providing a backing material on the third conducting material layer formed at step (g).

19. A method of manufacturing an ultrasonic transducer array according to claim 1, wherein step (e) includes forming plural grooves in parallel with one another so as to form plural ultrasonic transducers arranged on a curved surface in a one-dimensional manner.

20. A method of manufacturing an ultrasonic transducer array according to claim 3, wherein step (e) includes forming plural grooves in parallel with one another so as to form plural ultrasonic transducers arranged on a curved surface in a one-dimensional manner.

21. A method of manufacturing an ultrasonic transducer array according to claim 1, wherein step (e) includes forming plural grooves in two directions different from each other so as to form plural ultrasonic transducers arranged on the curved surface in a two-dimensional manner.

22. A method of manufacturing an ultrasonic transducer array according to claim 3, wherein step (e) includes forming plural grooves in two directions different from each other so as to form plural ultrasonic transducers arranged on the curved surface in a two-dimensional manner.

23. An ultrasonic transducer array comprising:
a backing material having a curved surface; and
plural ultrasonic transducers arranged on the curved surface of said backing material in a manner of one of directly and indirectly, each of said plural ultrasonic transducers including a first conducting material layer, a piezoelectric material layer and a second conducting material layer, and a surface of said piezoelectric material layer at an opposite side to said backing material having an area larger than that of another surface of said piezoelectric material layer at a side of the backing material.

24. An ultrasonic transducer array according to claim 23, wherein each of said plural ultrasonic transducers includes a first conducting layer, plural piezoelectric material layers, at least one internal electrode layer alternately stacked with said plural piezoelectric material layers and a second conducting material layer.

25. An ultrasonic transducer array according to claim 23, wherein each of said plural ultrasonic transducers includes an acoustic matching layer formed on said second conducting material layer.

26. An ultrasonic transducer array according to claim 23, wherein said second conducting material layer serves as an acoustic matching layer in each of said plural ultrasonic transducers.

27. An ultrasonic transducer array according to claim 23, wherein said plural ultrasonic transducers are arranged on the curved surface of said backing material in one of a one-dimensional manner and a two-dimensional manner.

28. An ultrasonic transducer array according to claim 27 for use of a radial scan method, wherein said backing material has a cylindrical shape, and said plural ultrasonic transducers are arranged around a side surface of the cylindrical shape.

29. A ultrasonic transducer array according to claim 27 of a convex type, wherein said backing material has a convex surface having a predetermined curvature.
